(19) United States
(12) Patent Application Publication
(10) Pub. No.: US 2026/0101662 A1
(43) Pub. Date: Apr. 9, 2026

(54) DISPLAY APPARATUS, ELECTRONIC DEVICE INCLUDING THE DISPLAY APPARATUS, AND METHOD OF MANUFACTURING THE DISPLAY APPARATUS

(71) Applicant: Samsung Display Co., Ltd., Yongin-si (KR)

(72) Inventor: Younggu Kim, Yongin-si (KR)

(21) Appl. No.: 19/178,294

(22) Filed: Apr. 14, 2025

(30) Foreign Application Priority Data
Oct. 7, 2024 (KR) 10-2024-0135974

(51) Int. Cl. H10K 59/80; H10K 102/00

(52) U.S. Cl. CPC H10K 59/873; H10K 59/879; H10K 2102/351

(57) ABSTRACT

A display apparatus includes: a substrate; a plurality of light-emitting diodes on the substrate; an encapsulation layer on the plurality of light-emitting diodes and comprising a first encapsulation layer and a second encapsulation layer on the first encapsulation layer; and an optical functional layer between the first encapsulation layer and the second encapsulation layer, wherein the optical functional layer has a refractive index in a range of 1.1 to 1.4 and an extinction coefficient in a range of 0.00001 to 0.01.

### CROSS-REFERENCE TO RELATED APPLICATION

The present application claims priority to and the benefit of Korean Patent Application No. 10-2024-0135974, filed on Oct. 7, 2024, in the Korean Intellectual Property Office, the entire disclosure of which is incorporated herein by reference.

### BACKGROUND

### 1. Field

Aspects of one or more embodiments relate to a display apparatus, an electronic device including the display apparatus, and a method of manufacturing the display apparatus.

### 2. Description of the Related Art

Various types of display devices, such as liquid crystal displays (LCDs), field emission displays (FEDs), light-emitting diodes (LEDs), etc., have been commercialized. For example, glasses-type monitors for implementing augmented reality (AR), virtual reality (VR), mixed reality (MR), or extended reality (XR) may be used as micro displays having a reduced pixel size in products such as head-mounted displays (HMDs), etc.

For improvement of the optical characteristics such as the resolution, luminance, light-emission efficiency, etc. required by the micro displays, efforts to develop liquid crystal on silicon (LCoS) and organic light-emitting diode on silicon (OLEDoS) have continued. OLEDoS is formed by a display technique using a wafer-based semiconductor process whereby an OLED is arranged on a semiconductor wafer substrate on which a complementary metal oxide semiconductor (CMOS) is arranged.

The above information disclosed in this Background section is only for enhancement of understanding of the background and therefore the information discussed in this Background section does not necessarily constitute prior art.

### SUMMARY

Aspects of one or more embodiments relate to a display apparatus, an electronic device including the display apparatus, and a method of manufacturing the display apparatus. The display apparatus according to one or more embodiments may include a light-emitting diode.

One or more embodiments include a display apparatus having excellent light-emission luminance and color reproduction. However, these characteristics are just an example and the scope of embodiments according to the present disclosure are not limited thereto.

Additional aspects will be set forth in part in the description which follows and, in part, will be apparent from the description, or may be learned by practice of the presented embodiments of the disclosure.

According to some embodiments of the present disclosure, a display apparatus includes a substrate, a plurality of light-emitting diodes arranged on the substrate, an encapsulation layer arranged on the plurality of light-emitting diodes and including a first encapsulation layer and a second encapsulation layer on the first encapsulation layer, and an optical functional layer arranged between the first encapsulation layer and the second encapsulation layer, wherein the optical functional layer has a refractive index of 1.1 to 1.4 and an extinction coefficient of 0.00001 to 0.01.

According to some embodiments, the optical functional layer may have a refractive index of 1.1 to 1.3.

According to some embodiments, the optical functional layer may have an extinction coefficient of 0.00001 to 0.001.

According to some embodiments, the optical functional layer may have a thickness of 0.4 μm to 2 μm.

According to some embodiments, the optical functional layer may have a thickness of 0.4 μm to 1 μm.

According to some embodiments, the substrate may include silicon, the first encapsulation layer may include an inorganic insulating material, and the second encapsulation layer may include an organic insulating material.

According to some embodiments of the present disclosure, an electronic device includes a display apparatus and a housing accommodating the display apparatus, wherein the display apparatus includes a substrate, a plurality of light-emitting diodes arranged on the substrate, an encapsulation layer arranged on the plurality of light-emitting diodes and including a first encapsulation layer and a second encapsulation layer on the first encapsulation layer, and an optical functional layer arranged between the first encapsulation layer and the second encapsulation layer, wherein the optical functional layer has a refractive index of 1.1 to 1.4 and an extinction coefficient of 0.00001 to 0.01.

According to some embodiments, the optical functional layer may have a refractive index of 1.1 to 1.3.

According to some embodiments, the optical functional layer may have an extinction coefficient of 0.00001 to 0.001.

According to some embodiments, the optical functional layer may have a thickness of 0.4 μm to 2 μm.

According to some embodiments, the optical functional layer may have a thickness of 0.4 μm to 1 μm.

According to some embodiments, the substrate may include silicon, the first encapsulation layer may include an inorganic insulating material, and the second encapsulation layer may include an organic insulating material.

According to some embodiments of the present disclosure, a method of manufacturing a display apparatus includes arranging a plurality of light-emitting diodes on a substrate, arranging a first encapsulation layer to cover the light-emitting diodes, arranging an optical functional layer on the first encapsulation layer, and arranging a second encapsulation layer on the optical functional layer, wherein the optical functional layer has a refractive index of 1.1 to 1.4 and an extinction coefficient of 0.00001 to 0.01.

According to some embodiments, the optical functional layer may have a refractive index of 1.1 to 1.3.

According to some embodiments, the optical functional layer may have an extinction coefficient of 0.00001 to 0.001.

According to some embodiments, the optical functional layer may have a thickness of 0.4 μm to 2 μm.

According to some embodiments, the optical functional layer may have a thickness of 0.4 μm to 1 μm.

According to some embodiments, the substrate may include silicon, the first encapsulation layer may include an inorganic insulating material, and the second encapsulation layer may include an organic insulating material.

According to some embodiments, the arranging of the optical functional layer and the arranging of the second encapsulation layer may be concurrently performed.

According to some embodiments, at least one of the arranging of the optical functional layer or the arranging of the second encapsulation layer may include an inkjet process.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view of an electronic device according to some embodiments;

FIG. 2 is an equivalent circuit diagram of a sub-pixel according to some embodiments;

FIG. 3 is a cross-sectional view of a display apparatus according to some embodiments;

FIG. 4 is a cross-sectional view of a display apparatus according to some embodiments;

FIG. 5 is a cross-sectional view of a display apparatus according to some embodiments;

FIG. 6 is a graph showing luminance of a display apparatus including an optical functional layer according to a refractive index of the optical functional layer, according to some embodiments;

FIG. 7 is a graph showing luminance of a display apparatus including an optical functional layer according to an extinction coefficient of the optical functional layer, according to some embodiments;

FIG. 8 is a graph showing transmittance of an optical functional layer according to a thickness of the optical functional layer according to some embodiments; and

FIGS. 9A to 9D are schematic cross-sectional views for describing a method of manufacturing a display apparatus, according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in more detail. The effects and characteristics of the disclosure and methods of achieving the same will become apparent by referring to the embodiments described below in more detail with reference to the drawings. However, embodiments according to the present disclosure are not limited to the embodiments disclosed hereinafter and may be realized in various forms.

Hereinafter, aspects of some embodiments will be described in more detail by referring to the accompanying drawings, wherein, when describing the accompanying drawings, elements that are the same as or corresponding to each other will be assigned the same reference numerals, repeated descriptions thereof will not be given.

In the embodiments described hereinafter, the terms “first,” “second,” etc. are used to distinguish an element from another and are not used as a restrictive sense.

As used herein, the singular expressions are intended to include the plural forms as well, unless the context clearly indicates otherwise.

It will be further understood that the terms “comprises” or “comprising” used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

Also, for convenience of explanation, elements in the drawings may have exaggerated or reduced sizes. For example, sizes and thicknesses of the elements in the drawings are randomly indicated for convenience of explanation, and thus, embodiments according to the present disclosure are not necessarily limited to the illustrations of the drawings.

When a certain embodiment may be implemented differently, a specific process order may be performed differently from the described order. For example, two consecutively described processes may be performed at the same time (or substantially at the same time) or performed in an order opposite to the described order.

In this specification, the expression “A and/or B” may indicate A, B, or A and B. Also, the expression “at least one of A and B” may indicate A, B, or A and B.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

An x-axis, a y-axis and a z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

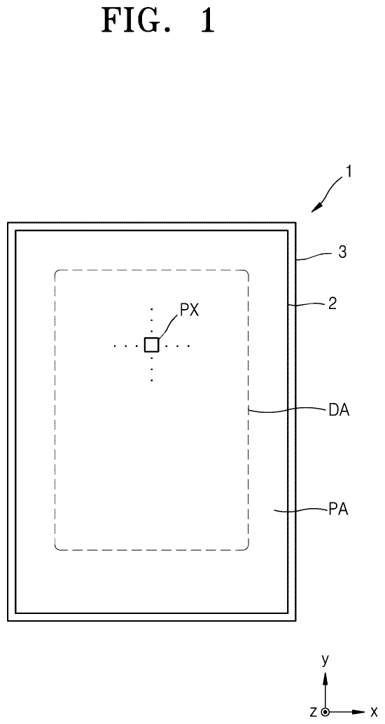

FIG. 1 is a plan view of an electronic device 1 according to some embodiments.

Referring to FIG. 1, the electronic device 1 may include a display apparatus 2 and a housing 3. The display apparatus 2 may be accommodated in the housing 3. For example, the housing 3 may totally surround the display apparatus 2.

The electronic device 1 may include not only portable electronic devices, such as a mobile phone, a smartphone, a tablet personal computer (PC), a mobile communication terminal, an electronic notebook, an electronic book, a portable multimedia player (PMP), a navigation device, an ultra-mobile PC (UMPC), etc., but also various products, such as a television, a notebook computer, a monitor, an advertising board, an Internet of things (IOT) device, etc. Also, the electronic device 1 according to some embodiments may include a wearable device, such as a smart watch, a watch phone, a glasses-type display, and a head-mounted display (HMD). Also, the electronic device 1 according to some embodiments may include a center information display (CID) on a gauge of a vehicle and a center fascia or a dashboard of a vehicle, a mirror display substituting a side-view mirror of a vehicle, or a display arranged on a rear surface of a front seat as an entertainment device for a backseat of a vehicle. The display apparatus 2 may be included in the electronic device 1 described above according to various embodiments as a component configured to display a motion image or a still image. FIG. 1 illustrates that the electronic device 1 includes a smartphone. However, embodiments according to the present disclosure are not necessarily limited thereto.

The display apparatus 2 may include a display area DA and a peripheral area PA which is a non-display area. A plurality of sub-pixels PX each including a display element may be arranged in the display area DA and may provide a certain image. The peripheral area PA may be an area where images are not displayed. A scan driver and a data driver configured to provide an electrical signal to be applied to the sub-pixels PX of the display area DA and power lines configured to provide a power supply such as a driving voltage and a common voltage may be arranged in the peripheral area PA. The sub-pixels PX may emit light of certain colors. The sub-pixels PX may emit light of the same colors or different colors. The plurality of sub-pixels PX may be grouped into one pixel. For example, three sub-pixels PX may be grouped into one pixel.

In this specification, a case in which the sub-pixel PX of the display apparatus 2 includes an organic light-emitting diode OLED as a display element, is mainly described. However, the display apparatus 2 is not limited thereto. According to some embodiments, the display apparatus 2 may include a light-emitting display apparatus including an inorganic light-emitting diode, that is, an inorganic light-emitting display apparatus. According to some embodiments, the display apparatus 2 may include a quantum dot light-emitting display apparatus.

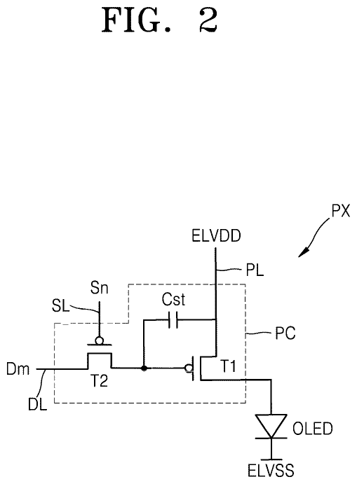

FIG. 2 is an equivalent circuit diagram of the sub-pixel PX according to some embodiments. Although FIG. 2 illustrates various components in a sub-pixel according to some embodiments, embodiments according to the present disclosure are not limited thereto, and according to some embodiments, the sub-pixel may include additional components without departing from the spirit and scope of embodiments according to the present disclosure.

A sub-pixel circuit PC may be electrically connected to a display element, and one display element may correspond to one sub-pixel PX. According to some embodiments, the display element may include an organic light-emitting diode OLED.

The sub-pixel circuit PC may include a first transistor T1, a second transistor T2, and a storage capacitor Cst. The second transistor T2 may include a switching transistor and may be connected to a scan line SL and a data line DL. The second transistor T2 may be turned on in response to a switching signal input from the scan line SL and configured to transmit a data signal input from the data line DL to the first transistor T1. The storage capacitor Cst may have an end electrically connected to the second transistor T2 and the other end electrically connected to a driving voltage line PL and may store a voltage corresponding to the difference between a voltage received from the second transistor T2 and a driving power voltage ELVDD supplied to the driving voltage line PL.

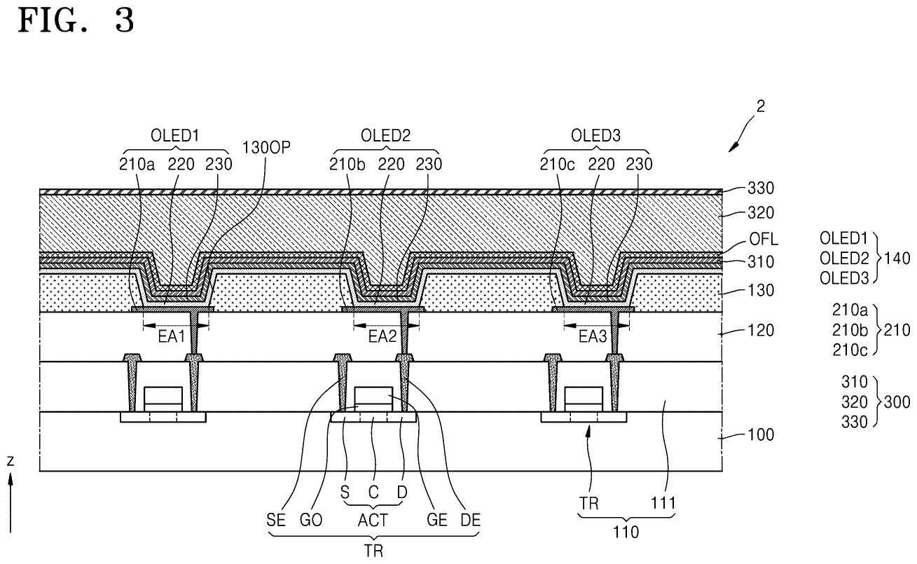

The first transistor T1 may include a driving transistor and may be connected to the driving voltage line PL and the storage capacitor Cst. The first transistor T1 may be configured to control a magnitude of a driving current flowing from the driving voltage line PL to the organic light-emitting diode OLED according to a value of the voltage stored in the storage capacitor Cst. The organic light-emitting diode OLED may emit light having a certain luminance according to the driving current. An opposite electrode 230 (see FIG. 3) of the organic light-emitting diode OLED may receive an electrode power voltage ELVSS.

With reference to FIG. 2, it is described that the sub-pixel circuit PC includes two transistors and one storage capacitor. However, embodiments according to the present disclosure are not limited thereto. For example, the number of transistors or the number of storage capacitors may be variously modified according to the design of the sub-pixel circuit PC.

FIG. 3 is a cross-sectional view of the display apparatus 2 according to some embodiments.

Referring to FIG. 3, the display apparatus 2 may include a substrate 100, a pixel circuit layer 110 including a transistor TR, a via layer 120 on the pixel circuit layer 110, a display element layer 140 on the via layer 120, and an encapsulation layer 300 on the display element layer 140.

The substrate 100 may include a semiconductor material, for example, a group IV semiconductor, a groups III-V compound semiconductor, or a groups II-VI compound semiconductor. That is, the substrate 100 may include a semiconductor substrate including a semiconductor material. For example, the substrate 100 may include silicon. That is, the substrate 100 may include a silicon substrate (a silicon semiconductor substrate). In this case, the substrate 100 may include a silicon wafer. The silicon wafer may include a monocrystalline silicon wafer, a polycrystalline silicon wafer, or an amorphous silicon wafer.

Like this, an organic light-emitting diode display apparatus using the semiconductor substrate as the substrate 100 may be referred to as an organic light-emitting diode on silicon (OLEDoS). For the OLEDoS, the semiconductor substrate may be used as the substrate 100, and thus, a manufacturing process commonly used in the semiconductor technical field may be used in a process of manufacturing the display apparatus. Thus, because it is possible to form and control an ultra-small pixel, the OLEDoS may display an ultra-high resolution image.

According to cases, types of the substrate 100 may not be limited to the semiconductor substrate. For example, the substrate 100 may include glass, metal, or polymer resins. The substrate 100 may include polymer resins, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may be variously modified. For example, the substrate 100 may have a multi-layered structure including two layers and a barrier layer between the two layers, wherein the two layers include the polymer resins described above and the barrier layer includes an inorganic material, such as silicon oxide (SiO₂), silicon nitride (SiNₓ), silicon oxynitride (SiON), etc. Hereinafter, a case where the substrate 100 includes a silicon substrate is mainly described in more detail.

The pixel circuit layer 110 may be arranged on the substrate 100. The pixel circuit layer 110 may include a plurality of sub-pixel circuit layers respectively corresponding to the plurality of sub-pixels PX described with reference to FIG. 1. Also, each of the plurality of sub-pixel circuits may include a transistor and/or a storage capacitor, as described with reference to FIG. 2. The pixel circuit layer 110 may include at least one transistor TR and at least one insulating layer.

FIG. 3 illustrates that an organic light-emitting diode OLED is arranged on the substrate 100 as a display element. That the organic light-emitting diode OLED is electrically connected to the sub-pixel circuit PC (see FIG. 2) may be understood as that a pixel electrode 210 of the organic light-emitting diode OLED is electrically connected to the transistor TR of the sub-pixel circuit PC. For convenience of illustration, FIG. 3 illustrates the transistor TR connected to each of first to third organic light-emitting diodes OLED1 to OLED 3. The transistor TR may correspond to the first transistor T1 (see FIG. 2) described above.

The transistor TR may include a gate insulating layer GO, a gate electrode GE, and an active layer ACT. The transistor TR may include, for example, a metal-oxide-semiconductor field-effect transistor (MOSFET), but embodiments according to the present disclosure are not limited thereto. According to some embodiments, each of the transistors TR may be isolated from each other by a device isolation area arranged between the transistors TR.

The active layer ACT may be arranged in the substrate 100. The active layer ACT may be formed as a portion of the substrate 100. A portion of the substrate 100 may be recessed, and the active layer ACT may be arranged on the recessed portion of the substrate 100. The active layer ACT may include a channel area C and a drain area D and a source area S at both sides of the channel area C. Each of the drain area D and the source area S may be an area of the substrate 100 including the semiconductor material, the area being doped with impurities. The channel area C may overlap the gate electrode GE. According to some embodiments, the active layer ACT may be arranged on an upper surface of the substrate 100. According to some embodiments, the active layer ACT may be integrally formed with the substrate 100.

The gate insulating layer GO may be arranged between the gate electrode GE and the active layer ACT. The gate insulating layer GO may include, for example, an inorganic insulating material, such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnO₂).

The gate electrode GE may be arranged on the active layer ACT. The gate electrode may overlap a portion of the active layer ACT. The channel area C of the transistor TR may be formed in a portion of the active layer ACT overlapping the gate electrode GE. The gate electrode GE may be arranged on the gate insulating layer GO. The gate electrode GE may include a conductive material. For example, the gate electrode GE may include metal nitride, such as titanium nitride (TiN), tantalum nitride (TaN), or tungsten nitride (WN), and/or a metal material, such as Al, W, Cu, or Mo, or a semiconductor material, such as doped polysilicon. The gate electrode GE may include layers or a single layer including the material described above.

An interlayer insulating layer 111 may be arranged on the substrate 100 and may cover the transistor TR. The interlayer insulating layer 111 may include at least one of oxide, nitride, or oxynitride. The interlayer insulating layer 111 may include a single layer or may be formed as a multi-layered structure.

A drain electrode DE and a source electrode SE may be arranged on the interlayer insulating layer 111. The drain electrode DE and the source electrode SE may be respectively connected to the drain area D and the source area S of the active layer ACT through a contact hole defined in the interlayer insulating layer 111. The drain electrode DE and the source electrode SE may include a conductive material.

The drain electrode DE and the source electrode SE may include a conductive material including Mo, Al, Cu, Ti, or the like and may include layers or a single layer including the material described above.

The via layer 120 may be arranged on the pixel circuit layer 110. The via layer 120 may cover the drain electrode DE and the source electrode SE. The via layer 120 may have a generally flat upper surface and may function as a planarization layer. The via layer 120 may include an organic insulating layer. The via layer 120 may include, for example, an organic material, such as acryl, benzocyclobutene (BCB), or hexamethyldisiloxane (HMDSO). The via layer 120 is illustrated as a single layer. However, the via layer 120 is not limited thereto and may be formed as a plurality of layers.

The display element layer 140 may be arranged on the via layer 120. The display element layer 140 may include the first organic light-emitting diode OLED1, the second organic light-emitting diode OLED2, and the third organic light-emitting diode OLED3.

Each of The first to third organic light-emitting diodes OLED1 to OLED3 may include a stack structure of the pixel electrode 210, an emission layer 220, and an opposite electrode 230. For example, the first organic light-emitting diode OLED1 may include a stack structure of a first pixel electrode 210a, the emission layer 220, and the opposite electrode 230. Similarly, the second organic light-emitting diode OLED2 may include a stack structure of a second pixel electrode 210b, the emission layer 220, and the opposite electrode 230. Similarly, the third organic light-emitting diode OLED3 may include a stack structure of a third pixel electrode 210c, the emission layer 220, and the opposite electrode 230.

According to some embodiments, the first to third organic light-emitting diodes OLED1 to OLED3 may emit light having the same wavelength area, that is, light having the same color. For example, each of the first to third organic light-emitting diodes OLED1 to OLED3 may emit white light.

According to some embodiments, the first to third organic light-emitting diodes OLED1 to OLED3 may emit light having different wavelength areas, that is, light having different colors. For example, the first organic light-emitting diode OLED1 may emit light having a first wavelength area in the range of 435 nanometers (nm) to 490 nm (or about 435 nm to about 490 nm), the second organic light-emitting diode OLED2 may emit light having a second wavelength area in the range of 500 nm to 590 nm (or about 500 nm to about 590 nm), and the third organic light-emitting diode OLED3 may emit light having a third wavelength area in the range of 600 nm to 710 nm (or about 600 nm to about 710 nm).

Areas in which the first to third organic light-emitting diodes OLED1 to OLED3 may emit light may be defined as first to third emission areas EA1, EA2, and EA3, respectively.

The plurality of pixel electrodes 210 may be arranged on the via layer 120. Each of the pixel electrodes 210 may be electrically connected to the transistor TR corresponding thereto, through a contact hole provided in the via layer 120. Each of the pixel electrodes 210 may include a transmissive conductive layer including transmissive conductive oxide, such as ITO, In₂O₃, or IZO, and a reflective layer including metal, such as Al or Ag. For example, each of the pixel electrodes 210 may have a triple-layered structure of ITO/Ag/ITO.

As illustrated in FIG. 3, the pixel electrodes 210 may include the first pixel electrode 210a, the second pixel electrode 210b, and the third pixel electrode 210c. The first to third pixel electrodes 210a to 210c may be arranged to be apart from one another, when viewed in a direction (for example, a z-axis direction) perpendicular to the substrate 100.

The emission layer 220 may be arranged on the pixel electrodes 210. The emission layer 220 may cover the pixel electrodes 210 on the via layer 120. The emission layer 220 may emit light of a certain color.

According to some embodiments, the emission layer 220 may be integrally formed across the plurality of pixel electrodes 210. In this case, the emission layer 220 may emit white light. In this case, the first to third organic light-emitting diodes OLED1 to OLED3 may emit light having the same color, as described above.

According to some embodiments, the emission layer 220 may be patterned to correspond to each of the plurality of pixel electrodes 210. In this case, the emission layer 220 corresponding to each of the plurality of pixel electrodes 210 may have a different emission spectrum. For example, the emission layer 220 may have an emission spectrum having a peak in the first wavelength area in the range of 435 nm to 490 nm (or about 435 nm to about 490 nm), the second wavelength area in the range of 500 nm to 590 nm (or about 500 nm to about 590 nm), and the third wavelength area in the range of 600 nm to 710 nm (or about 600 nm to about 710 nm). In this case, the first to third organic light-emitting diodes OLED1 to OLED3 may emit the light having different colors, as described above.

According to some embodiments, the emission layer 220 may include a high molecular-weight or low molecular-weight organic material. The emission layer 220 may include an organic emission layer. For example, the emission layer 220 may include a polymer material, such as a polyphenylene vinylene (PPV)-based material and a polyfluorene-based material. The emission layer 220 may be formed by using screen printing, inkjet printing, laser induced thermal imaging (LITI), etc. However, embodiments according to the present disclosure are not limited thereto. The emission layer 220 may include an inorganic light-emitting material or quantum-dots.

According to some embodiments, a functional layer may be arranged above and/or below the emission layer 220. The functional layer may include a hole injection layer (HIL), a hole transport layer (HTL), an electron transport layer (ETL), and/or an electron injection layer (EIL). The functional layer may be integrally formed across the plurality of pixel electrodes 210 or may be patterned to correspond to each of the plurality of pixel electrodes 210.

The opposite electrode 230 may be arranged on the pixel electrodes 210 and may overlap the pixel electrodes 210. The opposite electrode 230 may be arranged on the emission layer 220. The opposite electrode 230 may include a conductive material having a low work function. For example, the opposite electrode 230 may include a (semi) transparent layer including Ag, Mg, Al, Pt, Pd, Au, Ni, Nd, Ir, Cr, Li, Ca, or an alloy thereof. Alternatively, the opposite electrode 230 may further include a layer, such as ITO, IZO, ZnO, or In₂O₃, on the (semi-) transparent layer including the material described above. The opposite electrode 230 may be integrally formed to totally cover the substrate 100.

A pixel-defining layer 130 may be arranged on the via layer 120. The pixel-defining layer 130 may include openings 130OP corresponding to the first to third organic light-emitting diodes OLED1 to OLED3. Each of the openings 1300P of the pixel-defining layer 130 may expose at least a portion, for example, a central portion, of each of the pixel electrodes 210. According to some embodiments, the first to third emission areas EA1 to EA3 may be defined as areas exposed by the openings 1300P of the pixel-defining layer 130. The pixel-defining layer 130 may include an organic insulating material and/or an inorganic insulating material. The pixel-defining layer 130 may include, for example, an organic material, such as polyimide or HMDSO. The pixel-defining layer 130 may be omitted according to some embodiments.

The encapsulation layer 300 may be arranged on the opposite electrode 230. The encapsulation layer 300 may be arranged to cover the first to third organic light-emitting diodes OLED1 to OLED3. The encapsulation layer 300 may include at least one inorganic encapsulation layer and at least one organic encapsulation layer. According to some embodiments, the encapsulation layer 300 may include a first inorganic encapsulation layer 310, an organic encapsulation layer 320 on the first inorganic encapsulation layer 310, and a second inorganic encapsulation layer 330.

The first inorganic encapsulation layer 310 and/or the second inorganic encapsulation layer 330 may include one or more inorganic materials from among Al₂O₃, TiO₂, Ta₂O₅, HfO₂, ZnO₂, SiO₂, SiNₓ, and SION. The organic encapsulation layer 320 may include a polymer-based material. The polymer-based material may include acryl-based resins, epoxy-based resins, polyimide, polyethylene, etc. According to some embodiments, the organic encapsulation layer 320 may include acrylate. The organic encapsulation layer 320 may be formed by curing a monomer or by being coated with a polymer. The organic encapsulation layer 320 may be transparent.

An optical functional layer OFL may be arranged in the encapsulation layer 300. According to some embodiments, the optical functional layer OFL may be arranged between the first inorganic encapsulation layer 310 and the organic encapsulation layer 320, as illustrated in FIG. 3. According to some embodiments, the optical functional layer OFL may include an organic insulating material. According to some embodiments, the optical functional layer OFL may be integrally formed to totally cover the substrate 100.

The optical functional layer OFL may have a refractive index in a certain range. According to some embodiments, the optical functional layer OFL may have a refractive index of 1.1 to 1.4 (or about 1.1 to about 1.4). That is, the optical functional layer OFL may have a refractive index that is greater than or equal to 1.1 and less than or equal to 1.4 (or greater than or equal to about 1.1 and less than or equal to about 1.4). According to some embodiments, the optical functional layer OFL may have a refractive index of 1.1 to 1.3 (or about 1.1 to about 1.3). That is, the optical functional layer OFL may have a refractive index that is greater than or equal to 1.1 and less than or equal to 1.3 (or greater than or equal to about 1.1 and less than or equal to about 1.3). According to some embodiments, the optical functional layer OFL may have a refractive index of 1.1 to 1.2 (or about 1.1 to about 1.2). That is, the optical functional layer OFL may have a refractive index that is greater than or equal to 1.1 and less than or equal to 1.1 (or greater than or equal to about 1.1 and less than or equal to about 1.2). As a comparative example, the organic encapsulation layer 320 may have a refractive index of 1.55 (or about 1.55).

The optical functional layer OFL may have an extinction coefficient in a certain range. According to some embodiments, the optical functional layer OFL may have an extinction coefficient of 1*10⁻⁵ to 1*10⁻² (or about 1*10⁻⁵ to about 1*10⁻²). That is, the optical functional layer OFL may have an extinction coefficient that is greater than or equal to 0.00001 (or about 0.00001) and less than or equal to 0.001 (or about 0.001). According to some embodiments, the optical functional layer OFL may have an extinction coefficient of 1*10⁻³ to 1*10⁻³ (or about 1*10⁻³ to about 1*10⁻³). That is, the optical functional layer OFL may have an extinction coefficient that is greater than or equal to 0.00001 (or about 0.00001) and less than or equal to 0.001 (or about 0.001). According to some embodiments, the optical functional layer OFL may have an extinction coefficient of 1*10⁻³ to 1*10⁻³ (or about 1*10⁻³ to about 1*10⁻³). That is, the optical functional layer OFL may have an extinction coefficient that is greater than or equal to 0.00001 (or about 0.00001) and less than or equal to 0.0001 (or about 0.0001). As a comparative example, the organic encapsulation layer 320 may have an extinction coefficient of 0.01 (or about 0.01).

The optical functional layer OFL may have a thickness in a certain range. According to some embodiments, the optical functional layer OFL may have a thickness of 0.4 μm to 2 μm (or about 0.4 μm to about 2 μm). That is, the optical functional layer OFL may have a thickness that is greater than or equal to 0.4 μm (or about 0.4 μm) and less than or equal to 2 μm (or about 2 μm). According to some embodiments, the optical functional layer OFL may have a thickness of 0.4 μm to 1.5 μm (or about 0.4 μm to about 1.5 μm). That is, the optical functional layer OFL may have a thickness that is greater than or equal to 0.4 μm (or about 0.4 μm) and less than or equal to 1.5 μm (or about 1.5 μm). According to some embodiments, the optical functional layer OFL may have a thickness of 0.4 μm (or about 0.4 μm) to 1 μm (or about 1 μm). That is, the optical functional layer OFL may have a thickness that is greater than or equal to 0.4 μm (or about 0.4 μm) and less than or equal to 1 μm (or about 1 μm).

According to some embodiments, layers performing various functions, such as an input sensing layer, a color filter layer, etc., may further be arranged on the encapsulation layer 300.

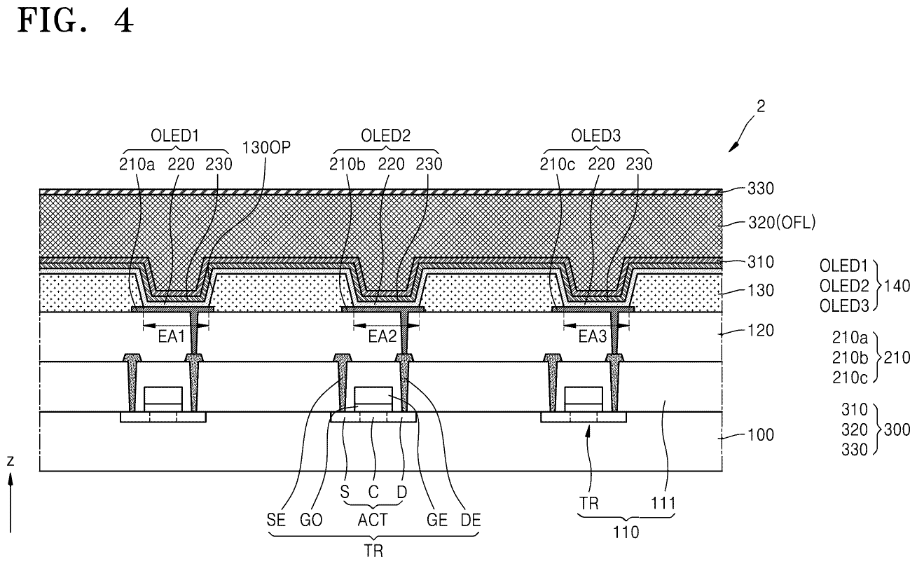

FIG. 4 is a cross-sectional view of the display apparatus 2 according to some embodiments.

Referring to FIG. 4, the organic encapsulation layer 320 and the optical functional layer OFL may be integrally formed. Both of the organic encapsulation layer 320 and the optical functional layer OFL may include an organic insulating material. According to some embodiments, when the organic encapsulation layer 320 includes the material the same as the material of the optical functional layer OFL, the corresponding layer may simultaneously (or concurrently) perform the functions of the organic encapsulation layer 320 and the optical functional layer OFL. In other words, the organic encapsulation layer 320 may be substituted by the optical functional layer OFL. In this case, the optical functional layer OFL may be formed to have a thickness appropriate to be formed as a planarization layer. Also, in this case, the optical functional layer OFL may be understood to be arranged between the first inorganic encapsulation layer 310 and the second inorganic encapsulation layer 330.

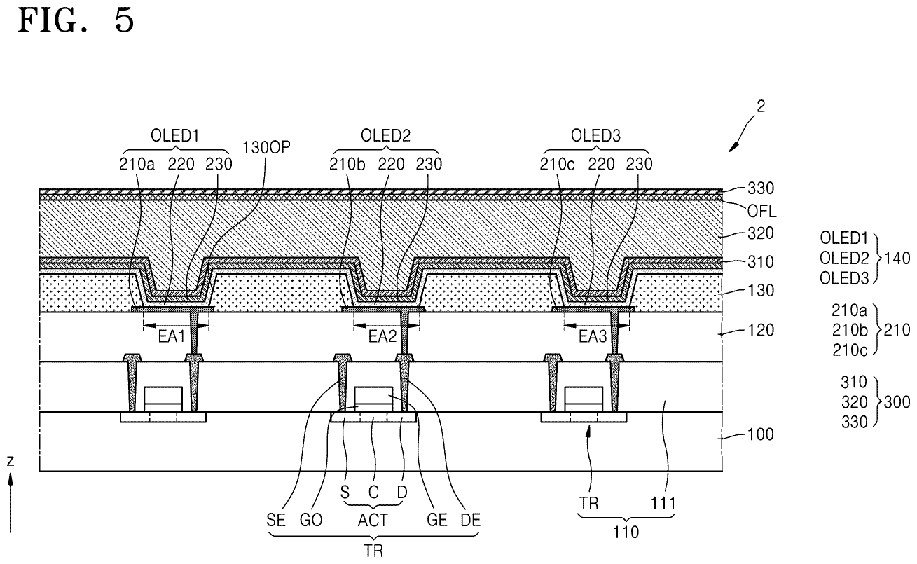

FIG. 5 is a cross-sectional view of the display apparatus 2 according to some embodiments.

Referring to FIG. 5, the optical functional layer OFL may be arranged between the organic encapsulation layer 320 and the second inorganic encapsulation layer 330. Other characteristics of the optical functional layer OFL may be the same as described with reference to FIG. 4.

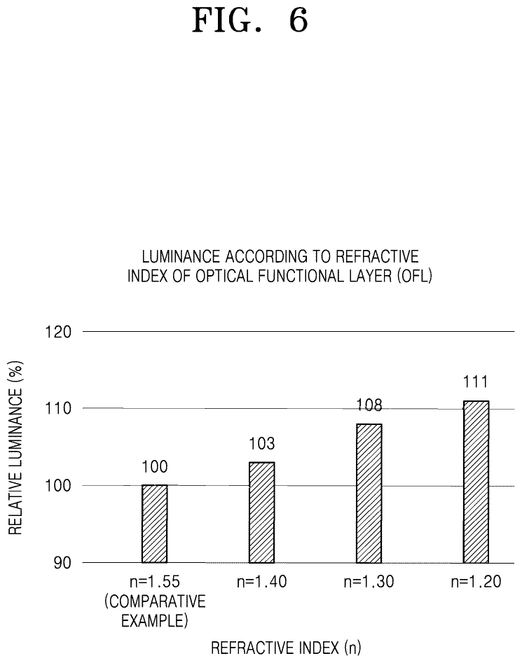

FIG. 6 is a bar graph showing luminance of a display apparatus including the optical functional layer OFL, according to a refractive index of the optical functional layer OFL, according to some embodiments.

Referring to FIG. 6, the x-axis of the graph indicates the refractive index of the optical functional layer OFL described above, wherein the refractive index is a relative value with no unit. The y-axis of the graph indicates a relative luminance represented as a percentage (%). The graph shows the relative luminance values with respect to the case of the comparative example having the refractive index of 1.55. According to some embodiments, the refractive index of 1.55 of the comparative example may correspond to the refractive index of the organic encapsulation layer 320 (see FIG. 3) described above.

When the refractive index of the optical functional layer OFL is 1.40, the relative luminance may be 103%. When the refractive index of the optical functional layer OFL is 1.30, the relative luminance may be 108%. When the refractive index of the optical functional layer OFL is 1.20, the relative luminance may be 111%. Through the graph of FIG. 6, it may be understood that as the refractive index of the optical functional layer OFL decreases, the luminance of the display apparatus may increase.

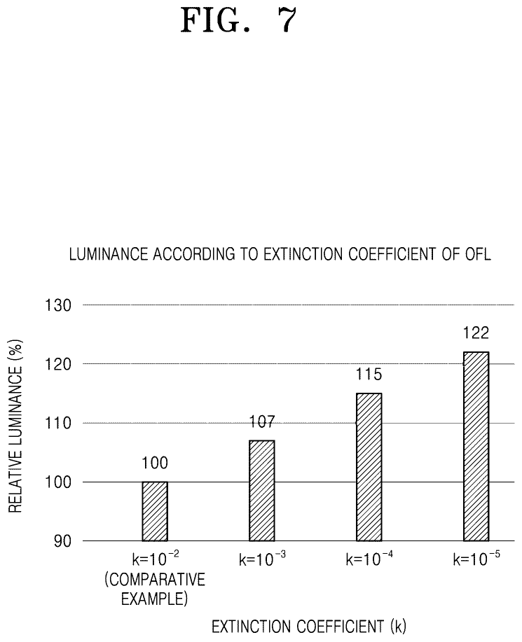

FIG. 7 is a graph showing luminance of a display apparatus including the optical functional layer OFL, according to an extinction coefficient of the optical functional layer OFL, according to some embodiments.

Referring to FIG. 7, the x-axis of the graph indicates the extinction coefficient of the optical functional layer OFL described above, wherein the extinction coefficient is a relative value with no unit. The y-axis of the graph indicates a relative luminance, which is represented as a percentage (%). The graph shows the relative luminance values with respect to the case of the comparative example having the extinction coefficient of 0.01. According to some embodiments, the extinction coefficient of 0.01 of the comparative example may correspond to the extinction coefficient of the organic encapsulation layer 320 (see FIG. 3) described above.

When the extinction coefficient of the optical functional layer OFL is 0.001, the relative luminance may be 107%. When the extinction coefficient of the optical functional layer OFL is 0.0001, the relative luminance may be 115%. When the extinction coefficient of the optical functional layer OFL is 0.00001, the relative luminance may be 122%. Through the graph of FIG. 7, it may be understood that as the extinction coefficient of the optical functional layer OFL decreases, the luminance of the display apparatus may increase.

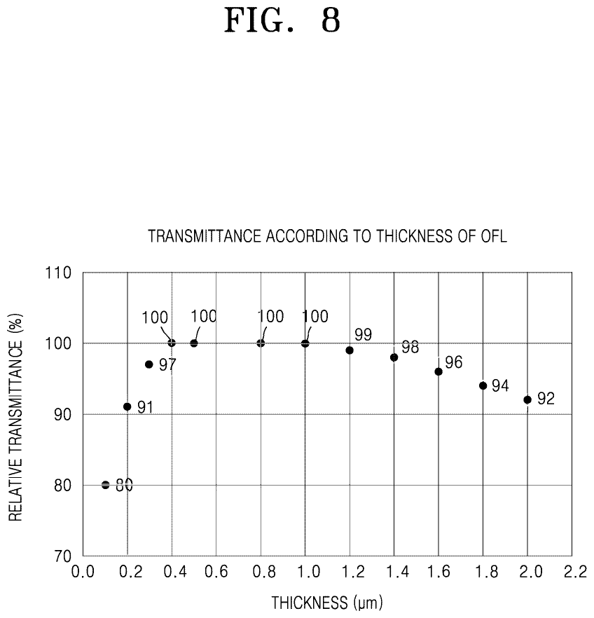

FIG. 8 is a graph showing transmittance of the optical functional layer OFL according to a thickness of the optical functional layer OFL, according to some embodiments.

Referring to FIG. 8, the x-axis of the graph indicates the thickness of the optical functional layer OFL described above, wherein the unit of the thickness of the optical functional layer OFL is μm. The y-axis of the graph indicates a relative transmittance represented as a percentage (%). The graph shows the relative transmittance values with respect to a case where the thickness of the optical functional layer OFL is 0.4 μm (or about 0.4 μm).

When the thickness of the optical functional layer OFL is 0.1 μm, the relative transmittance may be 80%. When the thickness of the optical functional layer OFL is 0.2 μm, the relative transmittance may be 91%. When the thickness of the optical functional layer OFL is 0.3 μm, the relative transmittance may be 97%. When the thickness of the optical functional layer OFL is 0.4 μm, the relative transmittance may be 100%. When the thickness of the optical functional layer OFL is 0.5 μm, the relative transmittance may be 100%. When the thickness of the optical functional layer OFL is 0.8 μm, the relative transmittance may be 100%. When the thickness of the optical functional layer OFL is 1.0 μm, the relative transmittance may be 100%. When the thickness of the optical functional layer OFL is 1.2 μm, the relative transmittance may be 99%. When the thickness of the optical functional layer OFL is 1.4 μm, the relative transmittance may be 98%. When the thickness of the optical functional layer OFL is 1.6 μm, the relative transmittance may be 96%. When the thickness of the optical functional layer OFL is 1.8 μm, the relative transmittance may be 94%. When the thickness of the optical functional layer OFL is 2.0 μm, the relative transmittance may be 92%.

Through the graph of FIG. 8, it may be understood that when the thickness of the optical functional layer OFL is 0.4 μm to 1.0 μm (or about 0.4 μm to about 1.0 μm), the optical functional layer OFL may have the highest transmittance value.

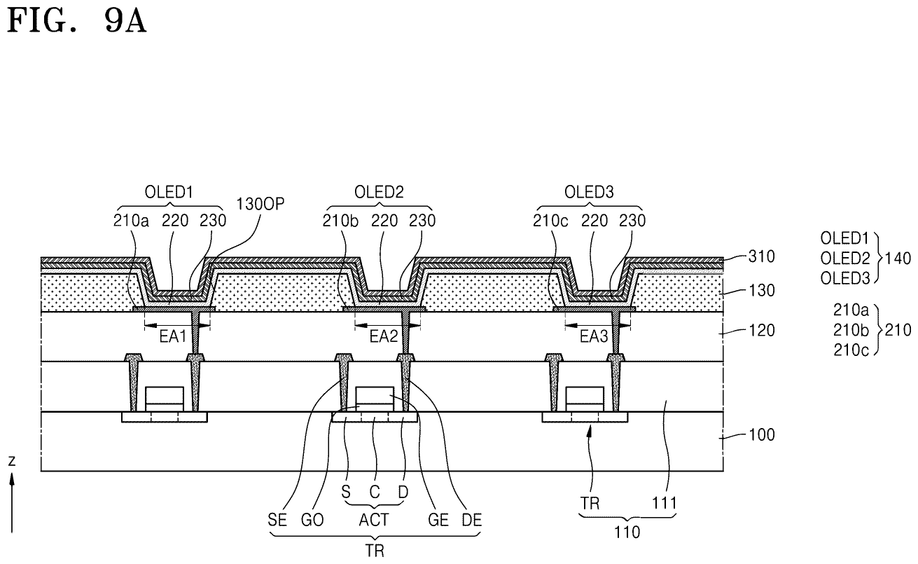

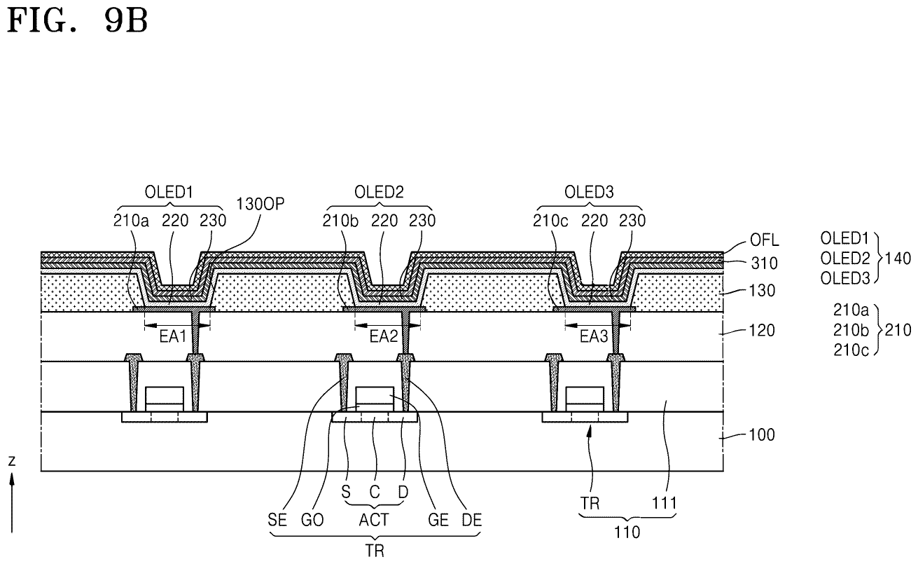

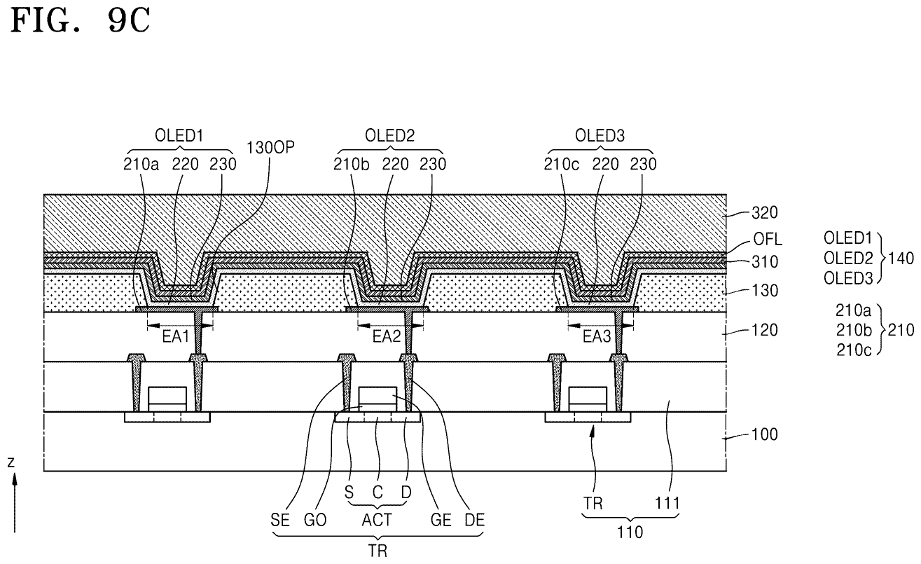

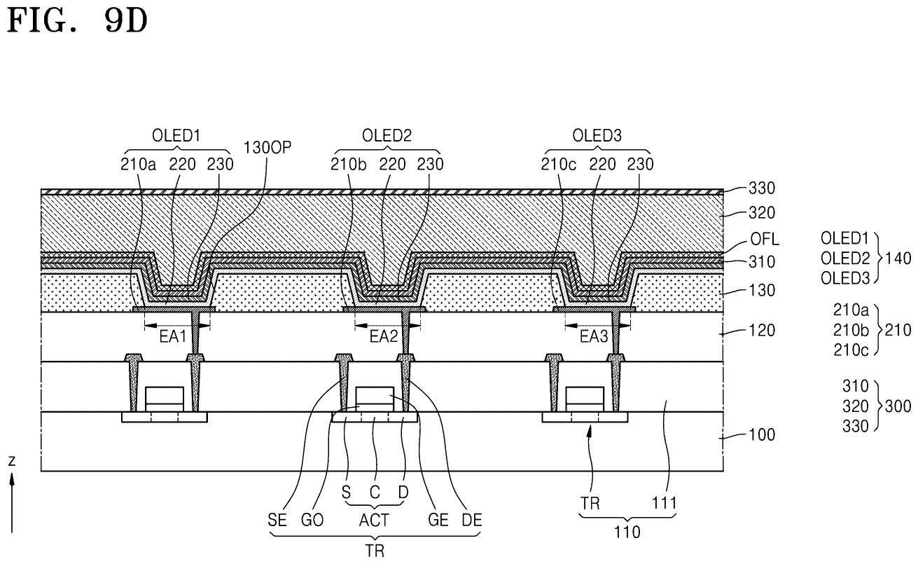

FIGS. 9A to 9D are schematic cross-sectional views for describing a method of manufacturing the display apparatus 2, according to some embodiments. FIGS. 9A to 9D illustrate a case where the embodiments illustrated in FIG. 3 is realized.

However, the process to be described below may also be used to realize the embodiments illustrated in FIG. 4 or 5.

Referring to FIG. 9A, the first inorganic encapsulation layer 310 may be arranged on the first to third organic light-emitting diodes OLED1 to OLED3. The first inorganic encapsulation layer 310 may totally cover the first to third organic light-emitting diodes OLED1 to OLED3. According to some embodiments, the first inorganic encapsulation layer 310 may include SiON. According to some embodiments, the first inorganic encapsulation layer 310 may be arranged by chemical vapor deposition (CVD).

Referring to FIG. 9B, the optical functional layer OFL may be arranged on the first inorganic encapsulation layer 310. The optical functional layer OFL may totally cover the first inorganic encapsulation layer 310. The characteristics of the optical functional layer OFL are as described above. According to some embodiments, the optical functional layer OFL may be arranged by using inkjet.

Referring to FIG. 9C, the organic encapsulation layer 320 may be arranged on the optical functional layer OFL. The organic encapsulation layer 320 may totally cover the optical functional layer OFL. According to some embodiments, the organic encapsulation layer 320 may include a planarization layer. According to some embodiments, the organic encapsulation layer 320 may be arranged by using inkjet. According to some embodiments, the optical functional layer OFL and the organic encapsulation layer 320 may be formed by the same process. That is, the process illustrated in FIG. 9B and the process illustrated in FIG. 9C may be performed as the same process.

Referring to FIG. 9D, the second inorganic encapsulation layer 330 may be arranged on the organic encapsulation layer 320. The second inorganic encapsulation layer 330 may totally cover the organic encapsulation layer 320. According to some embodiments, the second inorganic encapsulation layer 330 may include SiNₓ. According to some embodiments, the second inorganic encapsulation layer 330 may be arranged by atomic layer deposition (ALD).

A display apparatus according to some embodiments may have excellent light-emission luminance by additionally arranging an optical functional layer in a thin-film encapsulation layer. However, the scope of embodiments according to the present disclosure are not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, and their equivalents.

What is claimed is:

1. A display apparatus comprising:
a substrate;
a plurality of light-emitting diodes on the substrate;
an encapsulation layer on the plurality of light-emitting diodes and comprising a first encapsulation layer and a second encapsulation layer on the first encapsulation layer; and
an optical functional layer between the first encapsulation layer and the second encapsulation layer,
wherein the optical functional layer has a refractive index in a range of 1.1 to 1.4 and an extinction coefficient in a range of 0.00001 to 0.01.

2. The display apparatus of claim 1, wherein the optical functional layer has a refractive index in a range of 1.1 to 1.3.

3. The display apparatus of claim 1, wherein the optical functional layer has an extinction coefficient in a range of 0.00001 to 0.001.

4. The display apparatus of claim 1, wherein the optical functional layer has a thickness in a range of 0.4 micrometers (μm) to 2 μm.

5. The display apparatus of claim 4, wherein the optical functional layer has a thickness in a range of 0.4 μm to 1 μm.

6. The display apparatus of claim 1, wherein the substrate comprises silicon, the first encapsulation layer comprises an inorganic insulating material, and the second encapsulation layer comprises an organic insulating material.

7. An electronic device comprising a display apparatus and a housing accommodating the display apparatus, wherein the display apparatus comprises:
a substrate;
a plurality of light-emitting diodes on the substrate;
an encapsulation layer on the plurality of light-emitting diodes and comprising a first encapsulation layer and a second encapsulation layer on the first encapsulation layer; and
an optical functional layer between the first encapsulation layer and the second encapsulation layer, wherein
the optical functional layer has a refractive index in a range of 1.1 to 1.4 and an extinction coefficient in a range of 0.00001 to 0.01.

8. The electronic device of claim 7, wherein the optical functional layer has a refractive index in a range of 1.1 to 1.3.

9. The electronic device of claim 7, wherein the optical functional layer has an extinction coefficient in a range of 0.00001 to 0.001.

10. The electronic device of claim 7, wherein the optical functional layer has a thickness in a range of 0.4 micrometers (μm) to 2 μm.

11. The electronic device of claim 10, wherein the optical functional layer has a thickness in a range of 0.4 μm to 1 μm.

12. The electronic device of claim 7, wherein the substrate comprises silicon, the first encapsulation layer comprises an inorganic insulating material, and the second encapsulation layer comprises an organic insulating material.

13. A method of manufacturing a display apparatus, the method comprising:
arranging a plurality of light-emitting diodes on a substrate;
arranging a first encapsulation layer to cover the light-emitting diodes;
arranging an optical functional layer on the first encapsulation layer; and
arranging a second encapsulation layer on the optical functional layer,
wherein the optical functional layer has a refractive index in a range of 1.1 to 1.4 and an extinction coefficient in a range of 0.00001 to 0.01.

14. The method of claim 13, wherein the optical functional layer has a refractive index in a range of 1.1 to 1.3.

15. The method of claim 13, wherein the optical functional layer has an extinction coefficient in a range of 0.00001 to 0.001.

16. The method of claim 13, wherein the optical functional layer has a thickness in a range of 0.4 micrometers (μm) to 2 μm.

17. The method of claim 16, wherein the optical functional layer has a thickness in a range of 0.4 μm to 1 μm.

18. The method of claim 13, wherein the substrate comprises silicon, the first encapsulation layer comprises an inorganic insulating material, and the second encapsulation layer comprises an organic insulating material.

19. The method of claim 13, wherein the arranging of the optical functional layer and the arranging of the second encapsulation layer are concurrently performed.

20. The method of claim 13, wherein at least one of the arranging of the optical functional layer or the arranging of the second encapsulation layer comprises an inkjet process.
